(19) United States
(12) Patent Application Publication
(10) Pub. No.: US 2025/0362585 A1
(43) Pub. Date: Nov. 27, 2025

(54) MULTILAYER PROTECTION COATING WITH LAYERS OF DIFFERENT FUNCTIONS ON CARBON NANOTUBE

(71) Applicant: Taiwan Semiconductor Manufacturing Co., Ltd., Hsinchu (TW)

(72) Inventors: Pei-Cheng HSU, Hsinchu (TW); Huan-Ling LEE, Hsinchu (TW); Hsin-Chang LEE, Hsinchu (TW); Chin-Kun WANG, Hsinchu (TW)

(21) Appl. No.: 19/292,624

(22) Filed: Aug. 6, 2025

Related U.S. Application Data
(63) Continuation of application No. 18/404,776, filed on Jan. 4, 2024.
(60) Provisional application No. 63/581,167, filed on Sep. 7, 2023.
(60) Provisional application No. 63/609,264, filed on Dec. 12, 2023.

(51) Int. Cl. G03F 1/62; H01L 21/027

(52) U.S. Cl. CPC G03F 1/62; H01L 21/027

(57) ABSTRACT

A pellicle comprising a pellicle membrane with improved stability to hydrogen plasma is provided. The pellicle membrane includes a network of a plurality of carbon nanotubes. At least one carbon nanotube of the plurality of carbon nanotubes is surrounded by a multilayer protective coating that includes a stress control layer and a hydrogen permeation barrier layer over the stress control layer. The stress control layer and the hydrogen permeation barrier layer independently include an Me-containing nitride or an Me-containing oxynitride with Me selected from the group consisting of Si, Ti, Y, Hf, Zr, Zn, Mo, Cr and combinations thereof. The Me-containing nitride or the Me-containing oxynitride in the stress control layer has a first Me concentration, and the Me-containing nitride or the Me-containing oxynitride in the hydrogen permeation barrier layer has a second Me concentration less than the first Me concentration.

### PRIORITY CLAIM AND CROSS-REFERENCE

This application is a Continuation of U.S. application Ser. No. 18/404,776, filed Jan. 4, 2024, which claims the benefit of U.S. Provisional Patent Application No. 63/609,264, filed Dec. 12, 2023, which claims the benefit of U.S. Provisional Patent Application No. 63/581,167, filed Sep. 7, 2023, each of which is incorporated by reference herein in its entirety.

### BACKGROUND

In the semiconductor integrated circuit (IC) industry, technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing.

In a process of manufacturing the IC devices, a lithography process is employed to form a circuit pattern on a wafer. In the lithography process, a photomask is used to transfer a desired pattern onto the wafer. When the photomask is contaminated with foreign materials, such as particles, from the ambient environment, defects may occur on the wafer to which the pattern of the photomask is transferred.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system, in accordance with some embodiments.

FIG. 2A is a cross-sectional view of a pellicle-photomask structure, in accordance with some embodiments.

FIG. 2B is an isometric view of the pellicle-photomask structure of FIG. 2A, in accordance with some embodiments.

FIG. 2C illustrate a top view of a pellicle membrane of FIGS. 2A and 2B, in accordance with some embodiments.

FIG. 2D illustrates a cross-sectional view of a coated carbon nanotube of a network of carbon nanotubes illustrated in FIG. 2C, in accordance with some embodiments.

FIGS. 3A-3L are cross-sectional views of various examples of a multilayer protective coating illustrated in FIG. 2D, in accordance with some embodiments.

FIG. 4 is a flowchart illustrating a method for assembling a pellicle for a lithography process, in accordance with some embodiments.

FIG. 5 is a flowchart illustrating a method for forming a protective coating on a carbon nanotube, in accordance with some embodiments.

FIGS. 6A-6F are cross-section views of the protective coating at various stages of the method of FIG. 5, in accordance with some embodiments.

FIG. 7 is a flowchart illustrating a method for forming a protective coating on a carbon nanotube, in accordance with some embodiments.

FIGS. 8A-8F are cross-section views of the protective coating at various stages of the method of FIG. 7, in accordance with some embodiments.

FIG. 9 is a flowchart illustrating a method for fabricating a semiconductor device, in accordance with some embodiments.

FIGS. 10A-10D are cross-sectional views of the semiconductor device at various stages of the method of FIG. 9, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Photolithographic patterning processes use a photomask that includes a desired mask pattern. The photomask may be a reflective mask or a transmission mask. In the process, ultraviolet light is reflected off the surface of the photomask (for a reflective mask) or transmitted through the photomask (for a transmission mask) to transfer the pattern to a photoresist on a semiconductor wafer. The exposed portion of the photoresist is photochemically modified. After the exposure, the photoresist is developed to define openings in the photoresist, and one or more semiconductor processing steps (e.g. etching, epitaxial layer deposition, metallization, etc.) are performed which operate on those areas of the wafer surface exposed by the openings in the photoresist. After this semiconductor processing, the photoresist is removed by a suitable resist stripper or the like.

The minimum feature size of the pattern is limited by the light wavelength. Deep ultraviolet (UV) lithography, for example using a wavelength of 193 nm or 248 nm in some standard deep UV platforms, typically employs transmission masks and provides a smaller minimum feature size than lithography at longer wavelengths. Extreme ultraviolet (EUV) light, which spans wavelengths from 124 nm down to 10 nm, is currently being used to provide even smaller minimum feature size. At shorter wavelengths, particle contaminants on the photomask can cause defects in the transferred pattern. Thus, a pellicle is used to protect the photomask from such particle contaminants. The pellicle includes a pellicle membrane which is attached to a mounting frame. The mounting frame supports the pellicle membrane over the photomask. Any contaminating particles which land on the pellicle membrane are kept out of the focal plane of the photomask. As a result, defects in the transferred pattern are reduced or prevented.

As the pellicle membrane remains covering the photomask during exposure, it is subject to stringent requirements in terms of absorption, durability, and particle shielding capability, etc. In the realm of EUV lithography, finding suitable pellicle membrane materials with high transmission and stability at EUV wavelengths has been a challenge.

Carbon nanotubes (CNTs) emerge as one of the materials suitable for pellicle membranes in EUV reflective photomasks. CNTs exhibit high EUV transmission and mechanical stability, coupled with low EUV scattering and reflectivity. However, in the EUV lithography process, the pellicle membrane may be exposed to hydrogen plasma, posing a challenge as pristine CNTs are vulnerable to damage from hydrogen plasma due to the presence of crystalline defects on the CNT surfaces. Such damage may potentially shorten the lifespan of the pellicle membrane.

Embodiments of the present disclosure provide CNTs with enhanced resistance to hydrogen plasma etching through the formation of a multilayer protective coating as a shell around a CNT core. This multilayer protective coating comprises layers of different materials, each serving distinct functions, collectively producing a synergistic effect that diminishes the influx of hydrogen ions to the CNT surface. Consequently, the damage to CNTs due to hydrogen plasma etching is reduced. Pellicle membranes formed from these coated CNTs exhibit improved reliability and extended lifespan. In embodiments of the present disclosure, a pellicle membrane is formed of a network of a plurality of CNTs. Within this network, at least one CNT is coated with a multilayer protective coating including a stress control layer and a hydrogen permeation barrier layer. The hydrogen permeation barrier layer is configured to impede the passage of hydrogen ions, thus reducing the hydrogen plasma damage to the CNT during EUV exposure. The stress control layer is configured to minimize the formation of defects and cracks in the hydrogen permeation barrier layer, thereby decreasing the permeation of hydrogen ions. Optionally, the multilayer protective coating may include a hydrogen reduction layer comprising a plurality of nanostructures capable of reacting with hydrogen ions to further mitigate hydrogen plasma damage to the CNT during EUV exposure, and a diffusion inhibition layer to prevent agglomeration of these hydrogen reduction nanostructures, preserving the EUV transmittance of the pellicle membrane. As a result, such a pellicle membrane demonstrates improved etching resistance, high EUV transmittance, and enhanced durability.

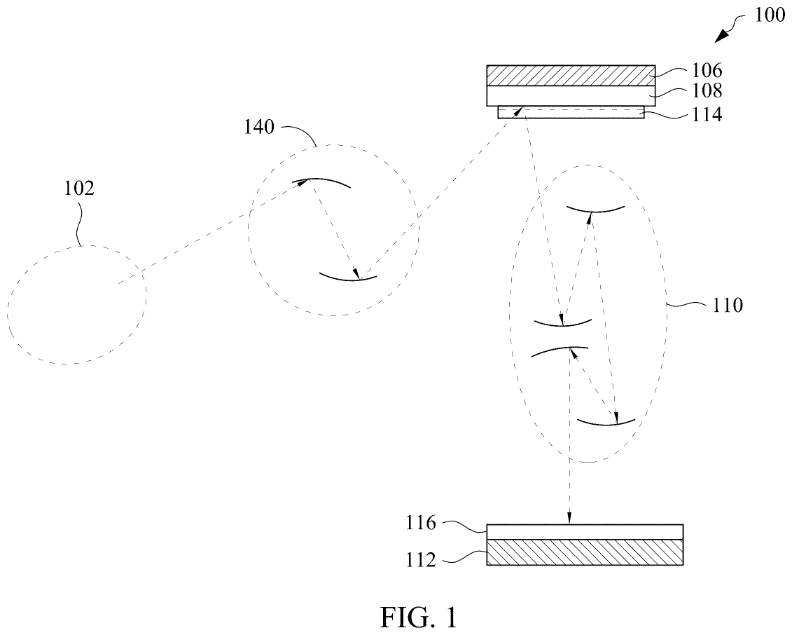

FIG. 1 is a schematic diagram of a lithography system 100, in accordance with some embodiments. The lithography system 100 may also be generically referred to as a “scanner” that is operable to perform lithographic processes including exposure with a respective radiation source and in a particular exposure mode.

In some embodiments, the lithography system 100 includes a high-brightness light source 102, an illuminator 104, a mask stage 106, a photomask 108, a projection optics module 110, and a substrate stage 112. In some embodiments, the lithography system 100 may include additional components that are not illustrated in FIG. 1. In some embodiments, one or more of the high-brightness light source 102, the illuminator 104, the mask stage 106, the photomask 108, the projection optics module 110, and the substrate stage 112 may be omitted from the lithography system 100 or may be integrated into combined components.

The high-brightness light source 102 may be configured to emit radiation having wavelengths in the range of approximately 1 nanometer (nm) to 250 nm. In some embodiments, the high-brightness light source 102 generates EUV light with a wavelength centered at approximately 13.5 nm; accordingly, in some embodiments, the high-brightness light source 102 may also be referred to as an “EUV light source.” However, it will be appreciated that the high-brightness light source 102 should not be limited to emitting EUV light. For instance, the high-brightness light source 102 may be utilized to perform any high-intensity photon emission from excited target material.

In embodiments where the lithography system 100 is a UV lithography system, the illuminator 104 may comprise various refractive optical components, such as a single lens or a lens system comprising multiple lenses (zone plates). In embodiments where the lithography system 100 is an EUV lithography system, the illuminator 104 may comprise various reflective optical components, such as a single mirror or a mirror system comprising multiple mirrors. The illuminator 104 may direct light from the high-brightness light source 102 onto the mask stage 106, and more particularly onto the photomask 108 that is secured onto the mask stage 106. In embodiments where the high-brightness light source 102 generates light in the EUV wavelength range, the illuminator 104 comprises reflective optics.

The mask stage 106 may be configured to secure the photomask 108. In some embodiments, the mask stage 106 may include an electrostatic chuck (e-chuck) to secure the photomask 108. This is because the gas molecules absorb EUV light, and the lithography system 100 for EUV lithography patterning is maintained in a vacuum environment to minimize EUV intensity loss. Herein, the terms “photomask,” “mask,” and “reticle” may be used interchangeably. In one example, the photomask 108 is a reflective mask.

In some embodiments, a pellicle 114 may be positioned over the photomask 108, for example, between the photomask 108 and the substrate stage 112. The pellicle 114 may protect the photomask 108 from particles and may keep the particles out of focus, so that the particles do not produce an image (which may cause defects on a wafer during the lithography process).

The projection optics module 110 may be configured for imaging the pattern of the photomask 108 onto a semiconductor wafer 116 secured on the substrate stage 112. In some embodiments, the projection optics module 110 comprises refractive optics (such as for a UV lithography system). In some embodiments, the projection optics module 110 comprises reflective optics (such as for an EUV lithography system). The light directed from the photomask 108, carrying the image of the pattern defined on the photomask 108, may be collected by the projection optics module 110. The illuminator 104 and the projection optics module 110 may be collectively referred to as an “optical module” of the lithography system 100.

In some embodiments, the semiconductor wafer 116 may be a bulk semiconductor wafer. For instance, the semiconductor wafer 116 may comprise a silicon wafer. The semiconductor wafer 116 may include silicon or another elementary semiconductor material, such as germanium. In some embodiments, the semiconductor wafer 116 may include a compound semiconductor. The compound semiconductor may include gallium arsenide, silicon carbide, indium arsenide, indium phosphide, another suitable material, or a combination thereof.

In some embodiments, the semiconductor wafer 116 includes a silicon-on-insulator (SOI) substrate. The SOI substrate may be fabricated using a separation by implantation of oxygen (SIMOX) process, a wafer bonding process, another applicable process, or a combination thereof.

In some embodiments, the semiconductor wafer 116 comprises an undoped substrate. However, in other embodiments, the semiconductor wafer 116 comprises a doped substrate, such as a p-type substrate or an n-type substrate.

In some embodiments, the semiconductor wafer 116 includes various doped regions (not shown) depending on the design requirements of the semiconductor device structure. The doped regions may include, for example, p-type wells and/or n-type wells. In some embodiments, the doped regions are doped with p-type dopants. For example, the doped regions may be doped with boron or boron fluoride. In other embodiments, the doped regions are doped with n-type dopants. For example, the doped regions may be doped with phosphor or arsenic. In some embodiments, some of the doped regions are p-doped and other doped regions are n-doped.

In some embodiments, an interconnection structure may be formed over the semiconductor wafer 116. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 116. Examples of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. Various processes may be used to form the various device elements, including deposition, etching, implantation, photolithography, annealing, and/or other applicable processes.

The device elements may be interconnected through the interconnection structure over the semiconductor wafer 116 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 116 may be coated with a photoresist layer that is sensitive to EUV light. Various components including those described above may be integrated together and may be operable to perform lithography exposing processes.

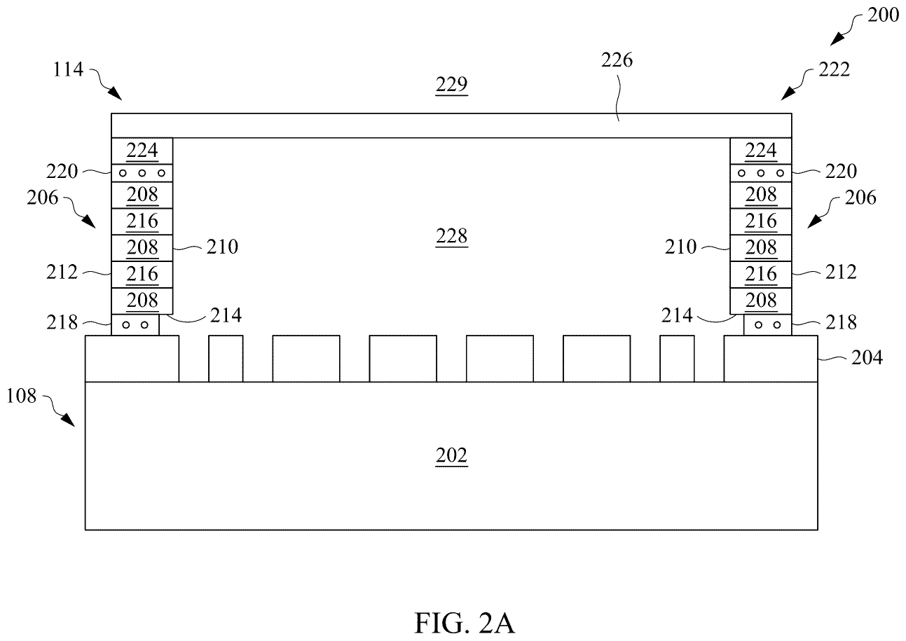

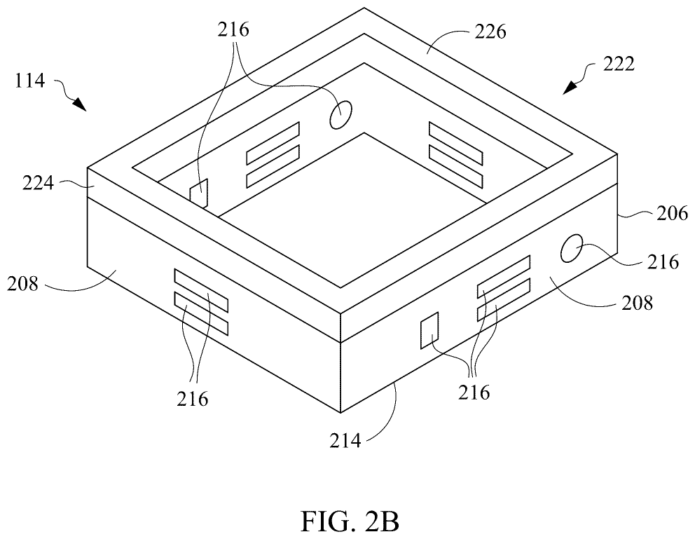

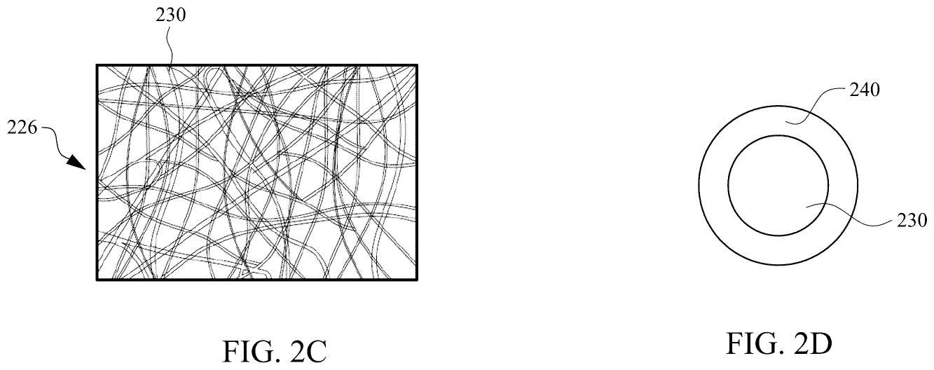

FIG. 2A is a cross-sectional view of a pellicle-photomask structure 200, according to some embodiments of the present disclosure. FIG. 2B is an isometric view of the pellicle-photomask structure 200 of FIG. 2A. As illustrated in FIGS. 2A and 2B, the photomask 108 may include a mask substrate 202 and a mask pattern 204 positioned over the mask substrate 202.

In some embodiments, the mask substrate 202 comprises a transparent substrate, such as fused silica that is relatively free of defects, borosilicate glass, soda-lime glass, calcium fluoride, a low thermal expansion material, an ultra-low thermal expansion material, or other applicable materials. The mask pattern 204 may be positioned over the mask substrate 202 as discussed above and may be designed according to the integrated circuit features to be formed over a semiconductor wafer (e.g., semiconductor wafer 116 of FIG. 1) during a lithography process. The mask pattern 204 may be formed by depositing a material layer and patterning the material layer to have one or more openings where beams of radiation may travel through without being absorbed, and one or more absorption areas which may completely or partially block the beams of radiation.

The mask pattern 204 may include metal, metal alloy, metal silicide, metal nitride, metal oxide, metal oxynitride, or other applicable materials. Examples of materials that may be used to form the mask pattern 204 may include, but are not limited to, Cr, MoₓSi_{y}, TaₓSi_{y}, Mo, NbₓO_{y}, Ti, Ta, CrₓN_{y}, MoₓO_{y}, MoₓN_{y}, CrₓO_{y}, TiₓN_{y}, ZrₓN_{y}, TiₓO_{y}, TaₓN_{y}, TaₓO_{y}, SiₓO_{y}, NbₓN_{y}, ZrₓN_{y}, AlₓO_{y}N_{z}, TaₓB_{y}O_{z}, TaₓB_{y}N_{z}, AgₓO_{y}, AgₓN_{y}, Ni, NiₓO_{y}, NiₓO_{y}N_{z}, and/or the like. The compound x/y/z ratio is not limited.

In some embodiments, the photomask 108 is an EUV mask. However, in some other embodiments, the photomask 108 may be an optical mask.

As illustrated in FIGS. 2A and 2B, the pellicle 114 may be positioned over the photomask 108. The pellicle 114 and the photomask 108 may form an enclosed inner volume 228 that is enclosed by the pellicle 114 and the photomask 108. The pellicle 114 and the photomask 108 separate the inner volume 228 from an outer environment 229. In some embodiments, the pellicle 114 includes a pellicle frame 206 that may be positioned over at least one of the mask substrate 202 and the mask pattern 204. In some embodiments, the pellicle frame 206 may be formed from Si, SiC, SiN, glass, a low coefficient of thermal expansion material (such as an Al alloy, a Ti alloy, Invar, Kovar, or the like), another suitable material, or a combination thereof. In some embodiments, suitable processes for forming the pellicle frame 206 may include machining processes, sintering processes, photochemical etching processes, other applicable processes, or a combination thereof.

In some embodiments, the pellicle frame 206 may include a side portion 208 having an inside surface 210 and an outside surface 212, where the inside surface 210 and the outside surface 212 are oriented on opposite sides of the side portion 208. The pellicle frame 206 may further include a bottom surface 214 or base that connects the inside surface 210 and the outside surface 212.

As further illustrated in FIGS. 2A and 2B, the pellicle-photomask structure 200 may further include a vent structure 216 formed in the side portion 208 and extending from the inside surface 210 through to the outside surface 212. In some embodiments, the vent structure 216 may comprise one or more apertures formed in the side portion 208 of the pellicle frame 206. The apertures may take any shape, including circular apertures, rectangular apertures, slit-shaped apertures, other shapes, or any combination thereof. The apertures may allow for a flow of air through a portion of the pellicle-photomask structure 200. In some embodiments, the vent structure 216 of the pellicle frame 206 may be formed so that at least one side portion 208 of the pellicle frame 206 includes one aperture formed in both the top of the side portion 208 (e.g., near the border 224) and another aperture formed in the bottom of the side portion 208 (e.g., near the mask pattern 204). In some embodiments, the apertures may include filters to minimize passage of outside particles through the vent structure 216.

In some embodiments, where the vent structure includes filters, the vent structure 216 may be formed together with the pellicle frame 206. In some embodiments, the vent structure 216 may be formed using a photochemical etching process, another applicable process, or a combination thereof.

In some other embodiments, where the vent structure includes filters, the vent structure 216 and the pellicle frame 206 may be formed separately, and an opening (not shown) may be formed in the side portion 208 of the pellicle frame 206. Afterwards, in some embodiments, the vent structure 216 may be placed into the opening in the side portion 208 of the pellicle frame 206. The vent structure 216 may then be bonded to the pellicle frame 206, e.g., by a brazing process, a direct diffusion bond process, a eutectic bonding process, another applicable process, or a combination thereof. In some embodiments, the vent structure 216 may prevent the pellicle membrane 226 from rupturing during the EUV lithography process.

As further illustrated in FIGS. 2A and 2B, the pellicle-photomask structure 200 may further include a pellicle frame adhesive 218 positioned between the pellicle frame 206 and the mask substrate 202.

In some embodiments, the pellicle frame adhesive 218 may be formed from a crosslink type adhesive, a thermoplastic elastomer type adhesive, a polystyrene type adhesive, an acrylic type adhesive, a silicon-based adhesive, an epoxy type adhesive, or a combination thereof.

In some embodiments, a surface treatment may be performed on the pellicle frame 206 to enhance the adhesion of the pellicle frame 206 to the pellicle frame adhesive 218. In some embodiments, the surface treatment may include an oxygen plasma treatment, another applicable treatment, or a combination thereof. However, in other embodiments, no surface treatment may be performed on the pellicle frame 206.

The pellicle-photomask structure 200 may further include a pellicle membrane adhesive 220 positioned over the pellicle frame 206. In some embodiments, the pellicle membrane adhesive 220 may be formed from a thermoplastic elastomer type adhesive, a polystyrene type adhesive, an acrylic type adhesive, a silicon-based adhesive, an epoxy type adhesive, another suitable adhesive, or a combination thereof. In some embodiments, the pellicle membrane adhesive 220 may be formed from a material that is different from the material making up the pellicle frame adhesive 218.

As further illustrated in FIGS. 2A and 2B, the pellicle-photomask structure 200 may further include a pellicle membrane assembly 222 positioned over the pellicle frame 206 and the pellicle membrane adhesive 220. As illustrated, the pellicle membrane adhesive 220 may be positioned between the pellicle membrane assembly 222 and the pellicle frame 206.

In some embodiments, the pellicle membrane assembly 222 may include a border 224 positioned over the pellicle membrane adhesive 220 and a pellicle membrane 226 positioned over the border 224. In some embodiments, the border 224 may be formed from Si. In further embodiments, the border 224 may be formed from boron carbide, graphene, carbon nanotube, SiC, SiN, SiO₂, SiON, Zr, Nb, Mo, Cd, Ru, Ti, Al, Mg, V, Hf, Ge, Mn, Cr, W, Ta, Ir, Zn, Cu, F, Co, Au, Pt, Sn, Ni, Te, Ag, another suitable material, an allotrope of any of these materials, or a combination thereof. The border 224 may mechanically support the pellicle membrane 226 around the periphery of the pellicle membrane 226. The border 224 may, in turn, be mechanically supported by the pellicle frame 206 when the pellicle-photomask structure 200 is fully assembled. That is, the pellicle frame 206 may mechanically support the border 224 and the pellicle membrane 226 of the pellicle membrane assembly 222 on the photomask 108.

In some embodiments, the pellicle membrane 226 may be formed from a network of a plurality of CNTs. The CNTs may be single-wall CNTs (SWCNTs), double-wall CNTs (DWCNTs), multi-wall CNTs (MWCNTs), or combinations thereof. The wall thickness of the CNTs may range from about 0.01 nm to about 100 nm. The CNTs in the pellicle membrane 226 may be individual, unbundled CNTs or bundled individual CNTs. The bundled individual CNTs form CNT bundles. The term “CNT bundle” refers to more than 10 individual CNTs wrapped around each other. While there is no theoretical limit, in particular embodiments a CNT bundle may be formed from a maximum of 20 CNTs. FIG. 2C, for instance, illustrates an example of the pellicle membrane 226 of FIGS. 2A and 2B. In the example illustrated in FIG. 2C, the pellicle membrane 226 includes a CNT membrane layer formed from randomly oriented CNTs 230. In some embodiments, the pellicle membrane 226 has a multi-layer structure comprising a plurality of CNT membrane layers. In some embodiments, each of the plurality of CNT membrane layers is formed from randomly oriented CNTs. In other embodiments, the plurality of CNT membrane layers are formed from directionally oriented CNTs with CNTs in adjacent layers aligned at an angle relative to each other.

In some embodiments, the network of CNTs 230 making up the pellicle membrane 226 may have a structure density of between 0.2 and 1, depending on the desired percentage of radiation to be transmitted by the pellicle membrane 226. For instance, the pellicle membrane 226 has been shown to achieve up to approximately 90% light transmittance. The precise structure density may be chosen to maximize EUV radiation transmission while minimizing passage of particles through the pellicle membrane 226. For instance, although a looser structure density may allow for greater EUV radiation transmission, the looser structure density may also allow particles to fall through to the photomask 108.

In some embodiments, the pellicle membrane 226 may have a thickness between 10 nm and 100 nm. In more particular embodiments, the thickness of the pellicle membrane 226 is between 20 nm and 50 nm. These ranges have been found to provide sufficient robustness to the pellicle membrane 226, while also providing high EUV transmission. In general, the thicker the pellicle membrane 226, the more robust the pellicle membrane 226 will be; however, if the pellicle membrane 226 is too thick, the percentage of EUV transmission may decrease. Thus, the disclosed ranges strike a balance between these two aims.

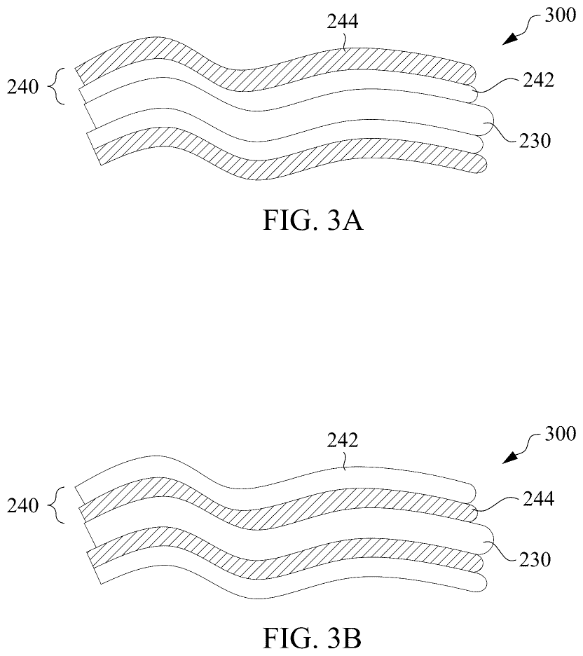

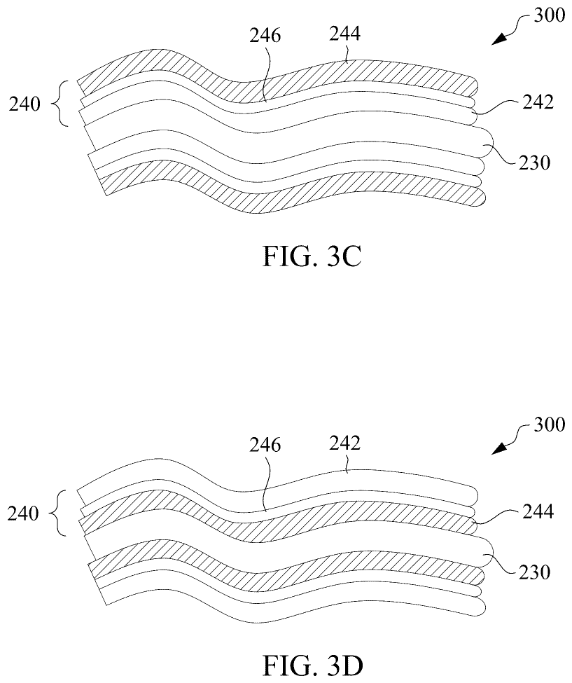

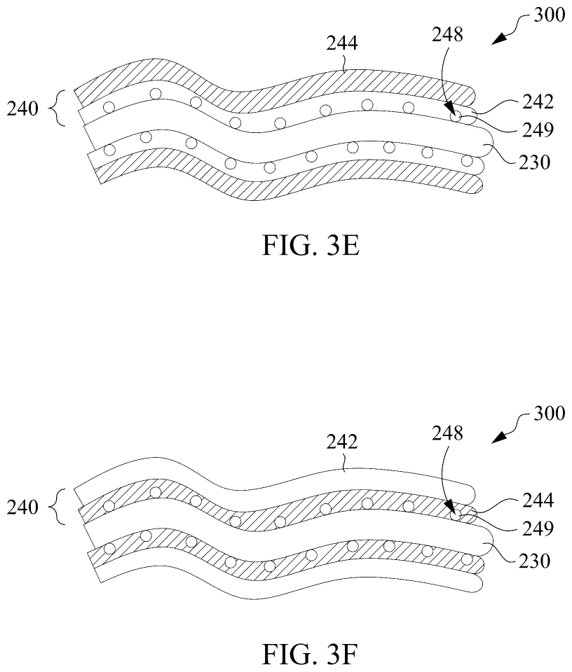

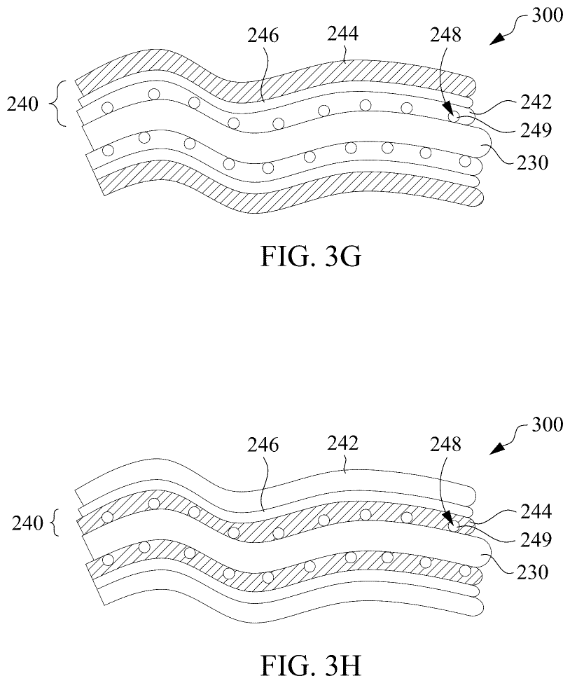

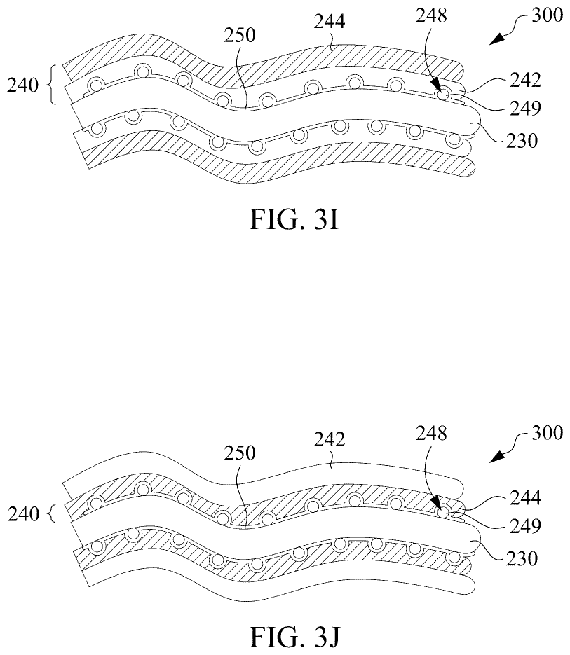

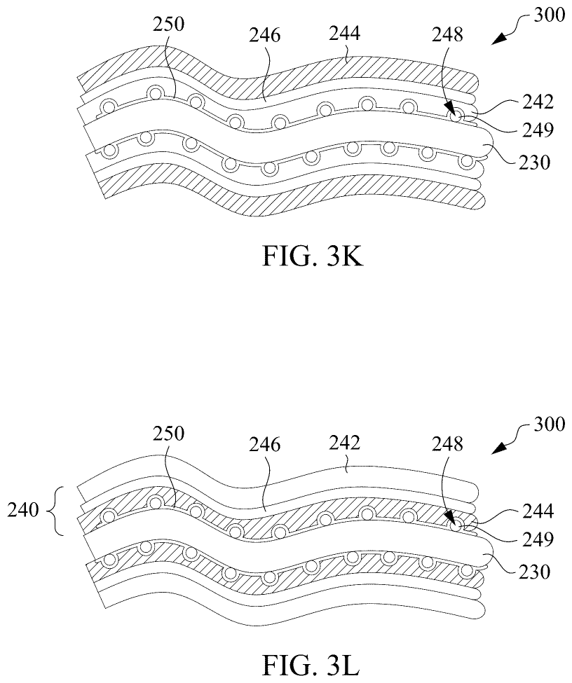

CNTs are susceptible to degradation from exposure to hydrogen plasma, such as the type employed during operation or maintenance of a photolithography system. To extend the CNT pellicle membrane lifetime in the scanner environment of EUV-induced hydrogen-based plasma, in embodiments of the present disclosure, one or more CNTs in the network of the plurality of CNTs are coated with a protective coating. For example, in some embodiments, more than 90% of individual CNTs in the network of the plurality of CNTs are coated with the protective coating. In some embodiments, more than 95%, more than 98%, or 100% of individual CNTs in the network of the plurality of CNTs are coated with the protective coating. FIG. 2D, for instance, illustrates a side cross-sectional view of a CNT 230 of the network of the plurality of CNTs illustrated in FIG. 2C. As shown in FIG. 2D, the CNT 230 is coated with a protective coating 240 to provide a coated CNT (e.g., coated CNT 300, FIGS. 3A-3L). The coated CNT has a core-shell structure including a CNT core and a protective coating shell. In embodiments of the present disclosure, the protective coating 240 features a multilayer structure comprising two or more layers of different materials, each serving distinct functions to prevent damage from hydrogen plasma to the CNT 230, as detailed below.

In some embodiments, a total thickness of the protective coating 240 is in the range from about 1 nm to about 40 nm. When the thickness of the protective coating 240 is greater than this range, EUV transmittance of the pellicle membrane 226 may be decreased, and when the thickness of the protective coating is smaller than this range, mechanical strength of the pellicle membrane 226 may be insufficient.

FIGS. 3A-3L are cross-sectional views illustrating various examples of a coated CNT 300 within the network of multiple CNTs, in accordance with embodiments of the present disclosure. The coated CNTs 300 depicted in FIGS. 3A-3L vary from each other based on the compositions of the protective coating 240 surrounding the CNT 230.

FIG. 3A is a cross-sectional view of a first example of a coated CNT 300 in the network of the plurality of CNTs 230, in according with some embodiments. As illustrated in FIG. 3A, the protective coating 240 that surrounds the CNT 230 has a bilayer structure including a stress control layer 242 over the CNT 230 and a hydrogen permeation barrier layer 244 over the stress control layer 242.

The stress control layer 242 physically contacts the outer surface of the CNT 230 and is adapted to reduce the stress between the CNT 230 and the hydrogen permeation barrier layer 244, thereby suppressing the formation of cracks and/or defects in the hydrogen permeation barrier layer 244. In some embodiments, the stress control layer 242 may include a metal-rich metal nitride or a silicon-rich silicon nitride with a metal or silicon content ranging from about 80 atomic (at) % to about 98 at %. In some embodiments, the metal is a transition metal selected from Ti, Y, Hf, Zr, Zn, Mo, Cr, and combinations thereof. The metal-rich or silicon-rich nitride is represented by the formula MeN, wherein Me is Si or a transition metal selected from Ti, Y, Hf, Zr, Zn, Mo, Cr, and combinations thereof, and a content of Me in MeN is from about 80 at % to about 98 at %. In some embodiments, the stress control layer 242 may include a metal-rich metal oxynitride or a silicon-rich silicon oxynitride with a metal or silicon content ranging from about 80 at % to about 98 at %. In some embodiments, the metal is a transition metal selected from Ti, Y, Hf, Zr, Zn, Mo, Cr, and combinations thereof. The metal-rich or silicon-rich oxynitride is represented by the formula MeON, wherein Me is Si or a transition metal selected from Ti, Y, Hf, Zr, Zn, Mo, Cr, and combinations thereof, and a content of Me in MeN is from about 80 at % to about 98 at %.

The stress control layer 242 is thin and thus does not degrade the transparency of the pellicle membrane 226 to EUV light. In some embodiments, the thickness of the stress control layer 242 may range from about 0.5 nm to about 10 nm. The stress control layer 242 may be formed by a suitable deposition technique, such as chemical vapor deposition (CVD), plasma enhanced CVD (PECVD), atomic layer deposition (ALD), plasma enhanced ALD (PEALD), physical vapor deposition (PVD), or other suitable techniques. In some embodiments, the stress control layer 242 is formed as a conformal layer surrounding the CNT 230.

The hydrogen permeation barrier layer 244 physically contacts the stress control layer 242 and is adapted to prevent or impede the transport of hydrogen ions therethrough, thereby preventing the damage to the CNTs induced by hydrogen plasma. In some embodiments, the hydrogen permeation barrier layer 244 is a nitrogen (N)- or oxygen (O)-rich nitride or N- or O-rich oxynitride layer. As used herein, the term “N or O-rich” means the content of N or O in the nitride or oxynitride constituting the hydrogen permeation barrier layer 244 is greater than the content of N or O in the nitride or oxynitride constituting the stress control layer 242. In some embodiments, the hydrogen permeation barrier layer 244 includes N- or O-rich silicon or metal nitride (represented by MeN with Me being Si or a transition metal), or N- or O-rich silicon or metal oxynitride (represented by MeON with Me being Si or a transition metal), with the N or O content ranging from about 10 at % to about 50 at %. In some embodiments, the metal is a transition metal selected from Ti, Y, Hf, Zr, Zn, Mo, Cr, and combinations thereof. In some embodiments, the hydrogen permeation barrier layer 244 includes N-rich silicon nitride (SiN) or silicon-rich oxynitride (SiON) with an N content ranging from about 10 at % to about 50 at %.

The hydrogen permeation barrier layer 244 is thin and thus does not degrade the transparency of the pellicle membrane 226 to EUV light. In some embodiments, the thickness of the hydrogen permeation barrier layer 244 may range from about 0.5 nm to about 10 nm. The hydrogen permeation barrier layer 244 may be formed by a suitable deposition technique, such as CVD, PECVD, ALD, PEALD, PVD, or other suitable techniques. In some embodiments, the hydrogen permeation barrier layer 244 is formed as a conformal layer surrounding the stress control layer 242.

In some embodiments, both the stress control layer 242 and the hydrogen permeation barrier layer 244 include SiN but with different Si and N contents. For example, in some embodiments, the stress control layer 242 is a Si-rich layer composed of SiN having a Si content in the range from about 80 at % to 90 at %, while the hydrogen permeation barrier layer 244 is a N-rich layer composed of SiN having a N content in the range from about 10 at % to 50 at %. The stress control layer 242 thus has a higher Si content than the hydrogen permeation barrier layer 244.

In some embodiments, both the stress control layer 242 and the hydrogen permeation barrier layer 244 include SiON but with different Si and N contents. For example, in some embodiments, the stress control layer 242 is a Si-rich layer composed of SiON having a Si content in the range from about 80 at % to 90 at %, while the hydrogen permeation barrier layer 244 is a N-rich layer composed of SiON having a N content in the range from about 10 at % to 50 at %. The stress control layer 242 thus has a higher Si content than the hydrogen permeation barrier layer 244.

FIG. 3B is a cross-sectional view of a second example of a coated CNT 300 in the network of the plurality of CNTs, in according with some embodiments. As illustrated in FIG. 3B, the protective coating 240 that surrounds the CNT 230 has a bilayer structure including a hydrogen permeation barrier layer 244 over the CNT 230, and a stress control layer 242 over the hydrogen permeation barrier layer 244. In contrast to the first example illustrated in FIG. 3A where the hydrogen permeation barrier layer 244 is the outermost layer of the protective coating 240, in the present example, the hydrogen permeation barrier layer 244 physically contacts the outer surface of the CNT 230, and the stress control layer 242 physically contacts the hydrogen permeation barrier layer 244. Consequently, in the present example, the stress control layer 242 is the outermost layer of the protective coating 240 and is formed after the hydrogen permeating barrier layer 244. The compositions and characteristics of the respective hydrogen permeation barrier layer 244 and the stress control layer 242 remain consistent with those described above in FIG. 3A, and will not be reiterated in detail herein.

FIG. 3C is a cross-sectional view of a third example of a coated CNT 300 in the network of the plurality of CNTs, in according with some embodiments. As illustrated in FIG. 3C, the protective coating 240 that surrounds the CNT 230 has a tri-layer structure including a stress control layer 242 over the CNT 230, an interdiffusion layer 246 over the stress control layer 242, and a hydrogen permeation barrier layer 244 over the interdiffusion layer 246. Comparing to the first example illustrated in FIG. 3A, in the present example, the protective coating 240 includes an additional interdiffusion layer 246 disposed between the stress control layer 242 and the hydrogen permeation barrier layer 244.

In some embodiments, the interdiffusion layer 246 includes a Si-rich or metal-rich nitride (represented by MeN with Me being Si or a transition metal), or a Si-rich or metal-rich oxynitride (represented by MeON with Me being Si or a transition metal). In some embodiments, the metal is a transition metal selected from Ti, Y, Hf, Zr, Zn, Mo, Cr, and combinations thereof. Comparing to the stress control layer 242 and the hydrogen permeation barrier layer 244, the interdiffusion layer 246 contains a lower amount of Si or metal than the stress control layer 242 but a higher amount of Si or metal than the hydrogen permeation barrier layer 244. In some embodiments, the interdiffusion layer 246 may exhibit a concentration gradient of Si or metal, with the concentration decreasing in the direction from the stress control layer 242 towards the hydrogen permeation barrier layer 244.

The interdiffusion layer 246 is thin and thus does not degrade the transparency of the pellicle membrane 226 to EUV light. In some embodiments, the thickness of the interdiffusion layer 246 may range from about 0.1 nm to about 5 nm. The interdiffusion layer 246 may be formed by thermal annealing that causes the silicon or metal atoms to diffuse from the stress control layer 242 and the hydrogen permeation barrier layer 244 into the interdiffusion layer 246. In some embodiments, the annealing temperature may be in the range from about 200° C. to about 1000° C.

FIG. 3D is a cross-sectional view of a fourth example of a coated CNT 300 in the network of the plurality of CNTs, in according with some embodiments. As illustrated in FIG. 3D, the protective coating 240 that surrounds the CNT 230 has a tri-layer structure including a hydrogen permeation barrier layer 244 over the CNT 230, an interdiffusion layer 246 over hydrogen permeation barrier layer 244, and a stress control layer 242 over the interdiffusion layer 246. In contrast to the third example illustrated in FIG. 3C, where the hydrogen permeation barrier layer 244 is the outermost layer of the protective coating 240, in the present example, the stress control layer 242 is the outermost layer of the protective coating 240 and is formed after the hydrogen permeation barrier layer 244.

FIG. 3E is a cross-sectional view of a fifth example of a coated CNT 300 in the network of the plurality of CNTs, in according with some embodiments. As illustrated in FIG. 3E, the protective coating 240 that surrounds the CNT 230 has a tri-layer structure including a hydrogen reduction layer 248 over the CNT 230, a stress control layer 242 over the hydrogen reduction layer 248 and the CNT 230, and a hydrogen permeation barrier layer 244 over the stress control layer 242. Comparing to the first example illustrated in FIG. 3A, in the present example, the protective coating 240 includes an additional hydrogen reduction layer 248 disposed on the surface of the CNT 230.

The hydrogen reduction layer 248 physically contacts the CNT 230 and is adapted to decrease the amount of hydrogen ions reaching the CNT 230, thereby preventing the damage to the CNT 230 caused by hydrogen plasma. In some embodiments, the hydrogen reduction layer 248 includes a metal that can react with hydrogen radicals (hydrogen ions) to form a hydrogen molecule (H+H=H₂), thereby decreasing the amount of hydrogen reaching the CNT 230. In some embodiments, the hydrogen reduction layer 248 includes a transition metal such as, for example, Ru, Mo, Zr, Ir, Pt, Rh, Nb, Ti, Cr, W, Co, or Fe. In some embodiments, the hydrogen reduction layer 238 includes a Group 13 metal such as, for example, Al or Ga.

The hydrogen reduction layer 248 may be formed as a continuous or discontinuous layer. Since the transition metals and Group 13 metals typically have a high EUV absorbance, a discontinuous layer is desirable as a continuous layer may decrease EUV transmission. In some embodiments, the hydrogen reduction layer 248 may include a plurality of nanostructures 249 having a dimension in the nanometer range. In some embodiments, the nanostructures 249 may have a dimension in the range from about 0.5 nm to about 6 nm. The nanostructures 249 can adopt any shapes or geometries. For example, in some embodiments, the nanostructure 249 may be nanograins, nanoislands, nanocubes, or nanosheets. In some embodiments and as shown in FIG. 3E, the hydrogen reduction layer 248 is a discontinuous layer including a plurality of nanograins embedded in the stress control layer 242. In some embodiments, the nanostructures 249 are uniformly distributed on the surface of CNT 230. In some other embodiments, the nanostructures 249 are randomly distributed on the surface of CNT 230. The spacing between adjacent nanostructures 249 is selected such that the nanostructures 249 will not block the transmission of the EUV light, while at the same time, can react with the hydrogen ions to prevent etching of the CNT 230 by hydrogen ions.

In some embodiments, the hydrogen reduction layer 248 may be formed by sol-gel, E-beam evaporation, CVD, ALD, PEALD, electrodeposition, or electroless deposition.

FIG. 3F is a cross-sectional view of a sixth example of a coated CNT 300 in the network of the plurality of CNTs, in according with some embodiments. As illustrated in FIG. 3F, the protective coating 240 that surrounds the CNT 230 has a tri-layer structure including a hydrogen reduction layer 248 over the CNT 230, a hydrogen permeation barrier layer 244 over the hydrogen reduction layer 248 and the CNT 230, and a stress control layer 242 over the hydrogen permeation barrier layer 244. In contrast to the fifth example illustrated in FIG. 3E, where the hydrogen permeation barrier layer 244 is the outermost layer of the protective coating 240, in the present example, the stress control layer 242 is the outermost layer of the protective coating 240 and is formed after the hydrogen permeation barrier layer 244. The nanostructures 249 are thus embedded in the hydrogen permeation barrier layer 244.

FIG. 3G is a cross-sectional view of a seventh example of a coated CNT 300 in the network of the plurality of CNTs, in according with some embodiments. As illustrated in FIG. 3G, the protective coating 240 that surrounds the CNT 230 has a four-layer structure including a hydrogen reduction layer 248 comprising a plurality of nanostructures 249 over the CNT 230, a stress control layer 242 over the nanostructures 249 and the CNT 230, an interdiffusion layer 246 over the stress control layer 242, and a hydrogen permeation barrier layer 244 over the interdiffusion layer 246. Comparing to the fifth example illustrated in FIG. 3E, in the present example, the protective coating 240 includes an additional interdiffusion layer 246 formed between the stress control layer 242 and the hydrogen permeation barrier layer 244. In some embodiments, the interdiffusion layer 246 may be formed by annealing the coated CNT 300 of FIG. 3E to cause diffusion of metal or Si atoms from the stress control layer 242 to the hydrogen permeation barrier layer 244.

FIG. 3H is a cross-sectional view of an eighth example of a coated CNT 300 in the network of the plurality of CNTs, in according with some embodiments. As illustrated in FIG. 3H, the protective coating 240 that surrounds the CNT 230 has a four-layer structure including a hydrogen reduction layer 248 comprising a plurality of nanostructures 249 over the CNT 230, a hydrogen permeation barrier layer 244 over the nanostructures 249 and the CNT 230, an interdiffusion layer 246 over the hydrogen permeation barrier layer 244, and a stress control layer 242 over the interdiffusion layer 246. In contrast to the seventh example illustrated in FIG. 3G, where the hydrogen permeation barrier layer 244 is the outermost layer of the protective coating 240, in the present example, the stress control layer 242 is the outermost layer of the protective coating 240 and is formed after the hydrogen permeation barrier layer 244.

FIG. 3I is a cross-sectional view of a ninth example of a coated CNT 300 in the network of the plurality of CNTs, in according with some embodiments. As illustrated in FIG. 3I, the protective coating 240 that surrounds the CNT 230 has a five-layer structure including a hydrogen reduction layer 248 comprising a plurality of nanostructures 249 over the CNT 230, a diffusion inhibition layer 250 over the nanostructures 249 and the CNT 230, a stress control layer 242 over the diffusion inhibition layer 250, and a hydrogen permeation barrier layer 244 over the stress control layer 242. Comparing to the fifth example illustrated in FIG. 3E, in the present example, the protective coating 240 includes an additional diffusion inhibition layer 250 on the exposed surfaces of nanostructures 249 and the CNT 230.

The diffusion inhibition layer 250 is adapted to prevent agglomeration of the nanostructures 249. Due to their small size and the high surface energy associated therewith, the nanostructures 249 tend to agglomerate to form larger aggregates when the heat is accumulated on the nanostructures 249 that causes migration or diffusion of the nanostructures 249. The aggregates decrease the EUV transmission of the pellicle membrane 226. Accordingly, the diffusion inhibition layer 250 that is formed on the nanostructures 249 encapsulates the nanostructures 249, and functions as a barrier to prevent migration or diffusion of the nanostructures 249, and thus suppresses agglomeration of nanostructures 249. As a result, the reliability of the pellicle membrane 226 is improved and the high EUV transmittance of the pellicle membrane 226 is maintained. In some embodiments, the diffusion inhibition layer 250 comprises a transition metal oxide or a Group 13 metal oxide. In some embodiments, the diffusion inhibition layer 250 comprises Y₂03, Al₂O₃, TiO₂, HfO₂, or combinations thereof.

The diffusion inhibition layer 250 is thin and thus does not degrade the transparency of the pellicle membrane 226 to EUV light. In some embodiments, the thickness of the diffusion inhibition layer 250 may range from about 0.1 nm to about 1 nm. The diffusion inhibition layer 250 may be formed by a suitable deposition technique, such as CVD, PECVD, ALD, PEALD, PVD, or other suitable technique. In some embodiments, the diffusion inhibition layer 250 is formed as a conformal layer surrounding the hydrogen reduction layer 248 and CNT 230.

FIG. 3J is a cross-sectional view of a tenth example of a coated CNT 300 in the network of the plurality of CNTs, in according with some embodiments. As illustrated in FIG. 3J, the protective coating 240 that surrounds the CNT 230 has a five-layer structure including a hydrogen reduction layer 248 comprising a plurality of nanostructures 249 over the CNT 230, a diffusion inhibition layer 250 over the nanostructures 249 and the CNT 230, a hydrogen permeation barrier layer 244 over the diffusion inhibition layer 250, and a stress control layer 242 over the hydrogen permeation barrier layer 244. In contrast to the ninth example illustrated in FIG. 3I, where the hydrogen permeation barrier layer 244 is the outermost layer of the protective coating 240, in the present example, the stress control layer 242 is the outermost layer of the protective coating 240 and is formed after the hydrogen permeation barrier layer 244.

FIG. 3K is a cross-sectional view of an eleventh example of a coated CNT 300 in the network of the plurality of CNTs, in according with some embodiments. As illustrated in FIG. 3K, the protective coating 240 that surrounds the CNT 230 has a six-layer structure including a hydrogen reduction layer 248 comprising a plurality of nanostructures 249 over the CNT 230, a diffusion inhibition layer 250 over the nanostructures 249 and the CNT 230, a stress control layer 242 over the diffusion inhibition layer 250, an interdiffusion layer 246 over the stress control layer 242, and a hydrogen permeation barrier layer 244 over the interdiffusion layer 246. Comparing to the ninth example illustrated in FIG. 3I, in the present example, the protective coating 240 includes an additional interdiffusion layer 246 between the stress control layer 242 and the hydrogen permeation barrier layer 244. In some embodiments, the interdiffusion layer 246 may be formed by annealing the coated CNT 300 of FIG. 3I to cause diffusion of metal from the stress control layer 242 to the hydrogen permeation barrier layer 244.

FIG. 3L is a cross-sectional view of a twelfth example of a coated CNT 300 in the network of the plurality of CNTs, in according with some embodiments. As illustrated in FIG. 3L, the protective coating 240 that surrounds the CNT 230 has a six-layer structure including a hydrogen reduction layer 248 comprising a plurality of nanostructures 249 over the CNT 230, a diffusion inhibition layer 250 over the nanostructures 249 and the CNT 230, a hydrogen permeation barrier layer 244 over the diffusion inhibition layer 250, an interdiffusion layer 246 over the a hydrogen permeation barrier layer 244, and a stress control layer 242 over the interdiffusion layer 246. In contrast to the eleventh example illustrated in FIG. 3K, where the hydrogen permeation barrier layer 244 is the outermost layer of the protective coating 240, in the present example, the stress control layer 242 is the outermost layer of the protective coating 240 and is formed after formation of the hydrogen permeation barrier layer 244.

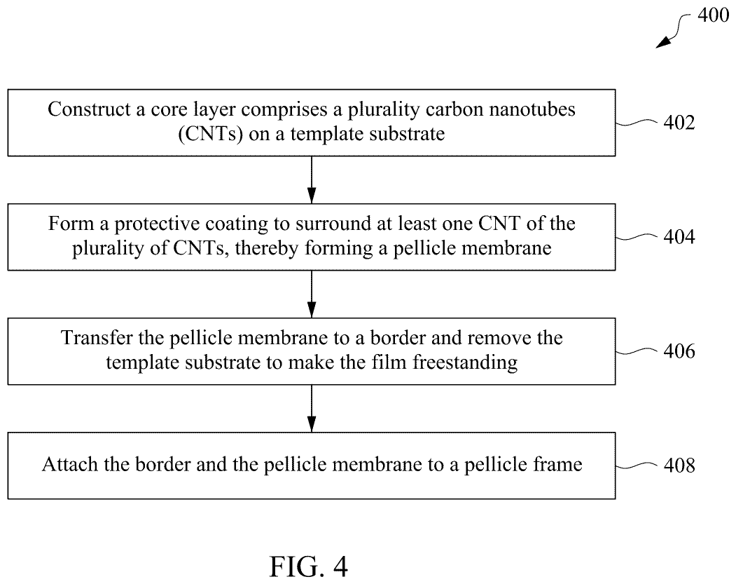

FIG. 4 is a flowchart illustrating a method 400 for assembling a pellicle for a lithography process, in accordance with some embodiments. For instance, the method 400 may be performed to assemble the pellicle 114 illustrated in FIGS. 1 and 2A-2B. The method 400 may be performed using one or more different machines, under the control of a controller or processor.

In step 402, a CNT core layer comprising a plurality of CNTs may be constructed on a template substrate. The plurality of CNTs may include a plurality of individual CNTs or a plurality of CNT bundles. The CNT may be a single-wall, double-wall, a multi-wall CNT, or combinations thereof. The template substrate may comprise, for instance, polyvinyl alcohol (PVA), polystyrene (PS), polyethylene terephthalate (PET), polyvinylidene fluoride (PVDF), or a chemical vapor deposited poly(p-xylylene) polymer (e.g., parylene C). In some embodiments, the CNT core layer may be constructed using a roll-to-roll process in a plasma environment, such as a plasma reacting chamber (in which the reacting gas may comprise, for instance, CₓH_{y}, H₂, Ar, O₂, another suitable gas, or any combination thereof).

In step 404, a protective coating is formed to surround at least one CNT of the plurality of CNTs, thereby forming a pellicle membrane, for example, pellicle membrane 226 (FIGS. 2A-2C). The processing steps for formation of the protective coating on the CNT will be described in detail below.

In step 406, the pellicle membrane may be transferred to a border, and the template substrate may be removed to make the pellicle membrane freestanding. In some embodiments, a dry transfer technique is used to transfer the pellicle membrane from the template substrate to the border. In some embodiments, the border is formed of silicon. The border may have a rectangular shape, as shown in FIG. 2B.

In step 408, the border and pellicle membrane may be attached to a pellicle frame including a vent structure. The pellicle frame may have the same shape as the border (e.g., rectangular shape), as shown in FIGS. 2A and 2B. In some embodiments, the pellicle frame may be formed from Si, SiC, SiN, glass, a low coefficient of thermal expansion material (e.g., an Al alloy, a Ti alloy, Invar, Kovar, or the like), another suitable material, or any combination thereof. In a further example, the pellicle frame may include a vent structure, for instance as illustrated in FIGS. 2A and 2B. That is, the vent structure may include apertures shaped like circles, rectangles, slits, other suitable shapes, or any combination thereof.

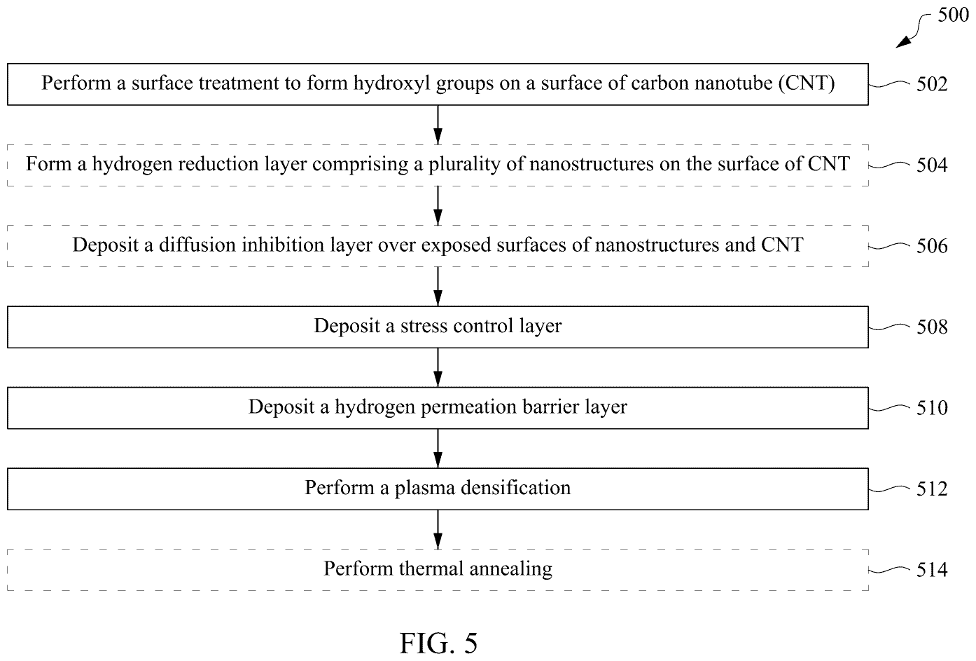

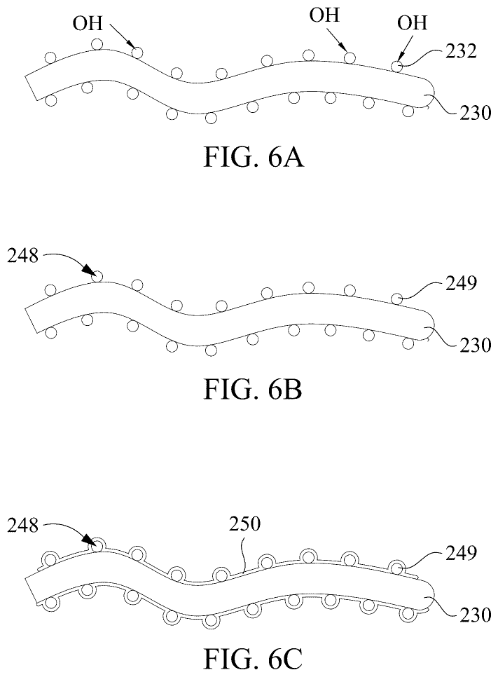

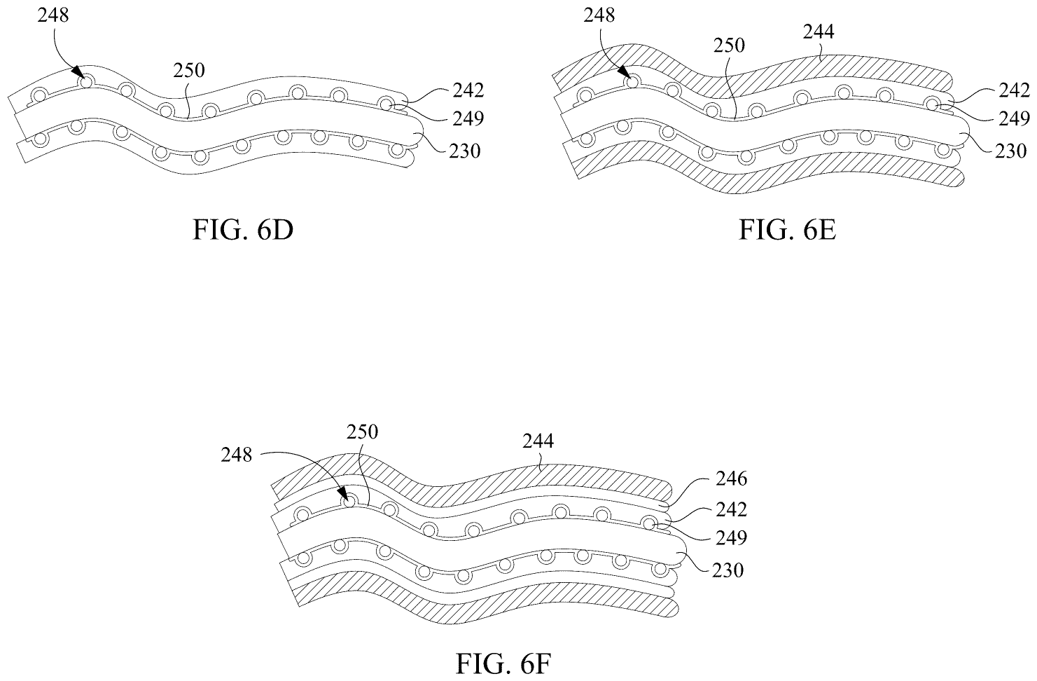

FIG. 5 is a flowchart illustrating a method 500 for forming a protective coating 240 on a CNT 230, in accordance with some embodiments. FIGS. 6A-6F are cross-sectional views of a coated CNT at various stages of the method 500, in accordance with some embodiments. The method 500 is discussed in detail below, with reference to the coated CNT of FIGS. 6A-6F.

In step 502, a surface treatment is performed to form hydroxyl (—OH) groups 232 on the CNT surface, as shown in FIG. 6A. The surface treatment improve the wettability of the CNT 230. The hydroxyl groups 232 also serve as the reactive sites for formation of nanostructures 249. In some embodiments, the surface treatment may be carried out by oxidative acid treatment using various type of acids and acid mixtures such as HNO₃, H₂SO₄/HNO₃, HCl/H₂SO₄/HNO₃, H₂O₂, KMnO₄, K₂Cr₂O₇/H₂SO₄, and KMnO₄/H₂SO₄.

In step 504, a hydrogen reduction layer 248 comprising a plurality of nanostructures 249 is formed on the surface of CNT 230, as shown in FIG. 6B. The hydrogen reduction layer 248 may include a plurality of nanograins, nanoislands, nanocubes, or nanosheets and may be formed by a sol-gel process, E-beam evaporation, CVD, ALD, PEALD, electrodeposition, electroless deposition, or other suitable deposition techniques. Step 504 is optional and is omitted in some embodiments.

In step 506, a diffusion inhibition layer 250 is deposited over exposed surfaces of the nanostructures 249 of the hydrogen reduction layer 248 and the CNT 230, as shown in FIG. 6C. The diffusion inhibition layer 250 is formed as a conformal layer and is deposited by a conformal deposition process such as CVD, PECVD, ALD, PEALD, or PVD. Step 506 is optional and is omitted in some embodiments.

In step 508, a stress control layer 242 is deposited over the diffusion inhibition layer 250, as shown in FIG. 6D or directly over the surface of the CNT 230 if steps 504 and 506 are omitted. The stress control layer 242 is formed as a conformal layer and is deposited by a conformal deposition process such as CVD, PECVD, ALD, PEALD, or PVD.

In step 510, a hydrogen permeation barrier layer 244 is deposited over the stress control layer 242, as shown in FIG. 6E. The hydrogen permeation barrier layer 244 is formed as a conformal layer and is deposited by a conformal deposition process such as CVD, PECVD, ALD, PEALD, or PVD.

In step 512, a densification process is performed to densify various layers coated on the CNT 230. In some embodiments, the densification process is conducted using Ar, N₂ or NH₃ plasma.

In step 514, an anneal process is performed. The annealing causes diffusion of metal or silicon from the stress control layer 242 to the hydrogen permeation barrier layer 244, thereby forming an interdiffusion layer 246 having a metal or silicon concentration gradient, as shown in FIG. 6F. In some embodiments, the annealing is a thermal annealing conducted at a temperature ranging from 200° C. to 1000° C. Step 514 is optional and is omitted in some embodiments.

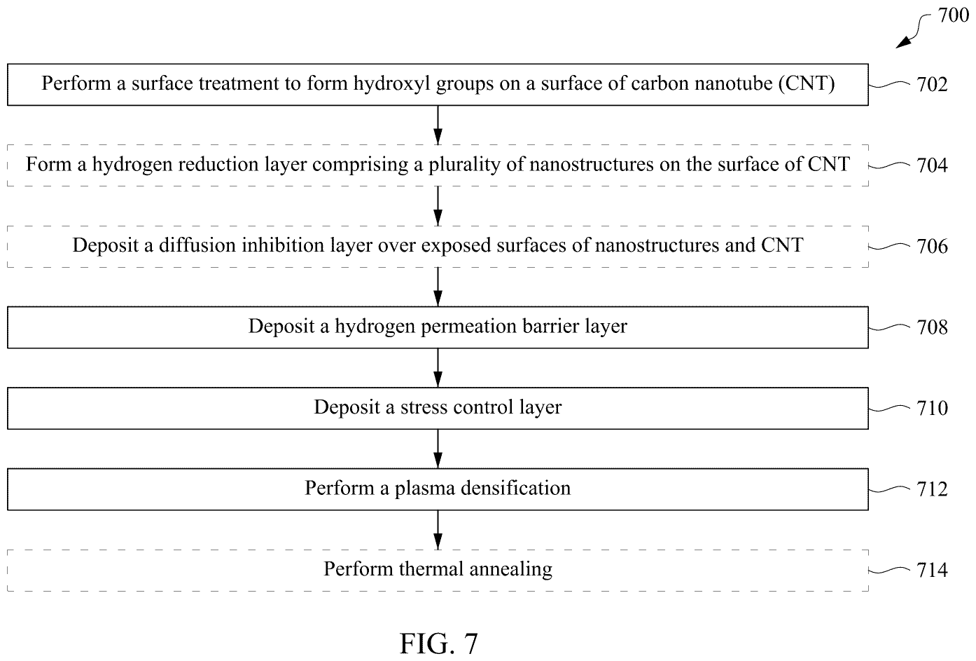

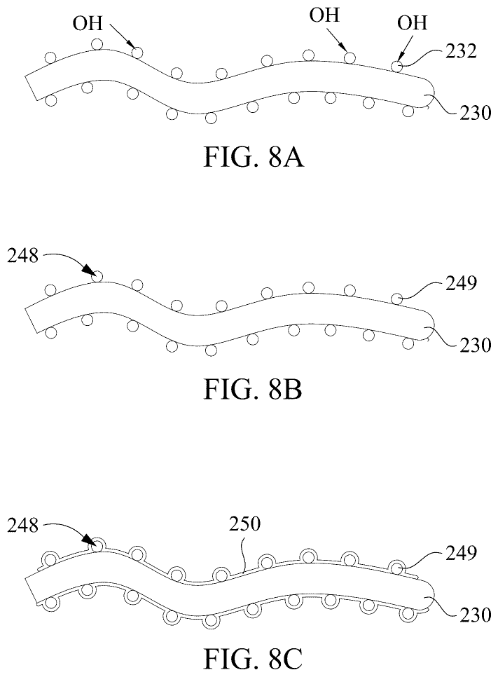

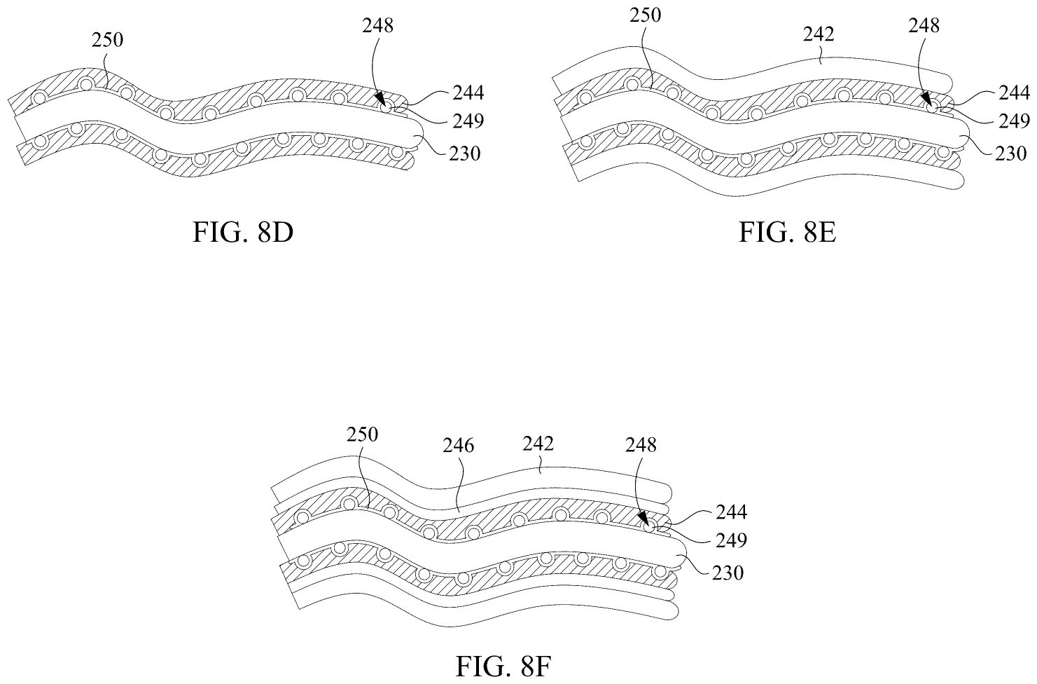

FIG. 7 is a flowchart illustrating a method 700 for forming a protective coating 240 on a CNT 230, in accordance with some embodiments. FIGS. 8A-8F are cross-sectional views of a coated CNT at various stages of the method 700, in accordance with some embodiments. The method 700 is discussed in detail below, with reference to the coated CNT of FIGS. 8A-8F.

In step 702, a surface treatment is performed to form hydroxyl (—OH) groups 232 on the CNT surface, as shown in FIG. 8A. The surface treatment improve the wettability of the CNT 230. The hydroxyl groups 232 also serve as the reactive sites for formation of nanostructures 249. In some embodiments, the surface treatment may be carried out by oxidative acid treatment using various type of acids and acid mixtures such as HNO₃, H₂SO₄/HNO₃, HCl/H₂SO₄/HNO₃, H₂O₂, KMnO₄, K₂Cr₂O₇/H₂SO₄, and KMnO₄/H₂SO₄.

In step 704, a hydrogen reduction layer 248 comprising a plurality of nanostructures 249 is formed on the surface of CNT 230, as shown in FIG. 8B. The hydrogen reduction layer 248 may include a plurality of nanograins, nanoislands, nanocubes, or nanosheets and may be formed by a sol-gel process, E-beam evaporation, CVD, ALD, PEALD, electrodeposition, electroless deposition, or other suitable deposition techniques. Step 704 is optional and is omitted in some embodiments.

In step 706, a diffusion inhibition layer 250 is deposited over exposed surfaces of the nanostructures 249 of the hydrogen reduction layer 248 and the CNT 230, as shown in FIG. 8C. The diffusion inhibition layer 250 is formed as a conformal layer and is deposited by a conformal deposition process such as CVD, PECVD, ALD, PEALD, or PVD. Step 706 is optional and is omitted in some embodiments.

In step 708, a hydrogen permeation barrier layer 244 is deposited over the diffusion inhibition layer 250, as shown in FIG. 8D or directly over the surface of the CNT 230 if steps 704 and 706 are omitted. The hydrogen permeation barrier layer 244 is formed as a conformal layer and is deposited by a conformal deposition process such as CVD, PECVD, ALD, PEALD, or PVD.

In step 710, a stress control layer 242 is deposited over the hydrogen permeation barrier layer 244, as shown in FIG. 8E. The stress control layer 242 is formed as a conformal layer and is deposited by a conformal deposition process such as CVD, PECVD, ALD, PEALD, or PVD.

In step 712, a densification process is performed to densify various layers coated on the CNT 230. In some embodiments, the densification process is conducted using Ar, N₂ or NH₃ plasma.

In step 714, an anneal process is performed. The annealing causes diffusion of metal or silicon from the stress control layer 242 to the hydrogen permeation barrier layer 244, thereby forming an interdiffusion layer 246 having a metal or silicon concentration gradient, as shown in FIG. 8F. In some embodiments, the annealing is a thermal annealing conducted at a temperature ranging from 200° C. to 1000° C. Step 714 is optional and is omitted in some embodiments.

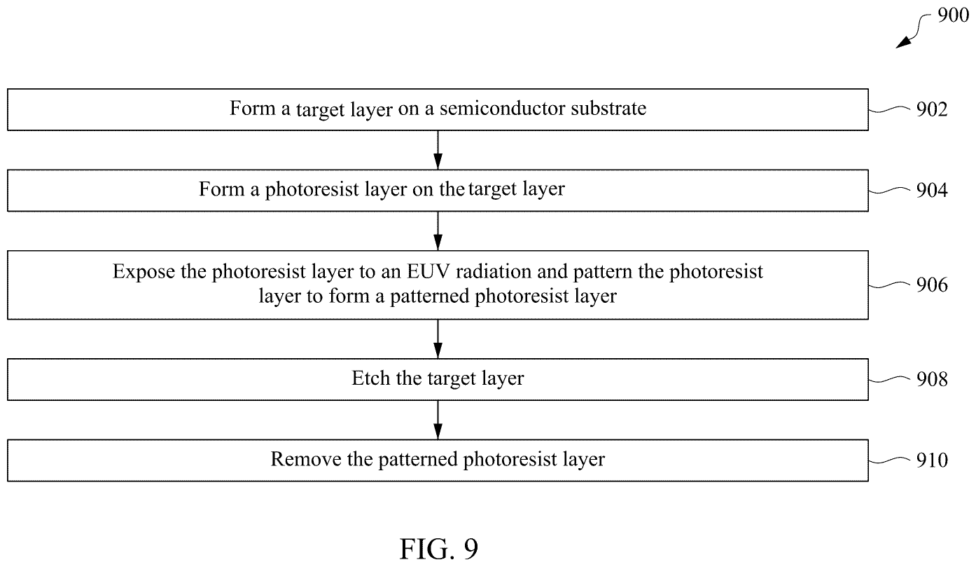

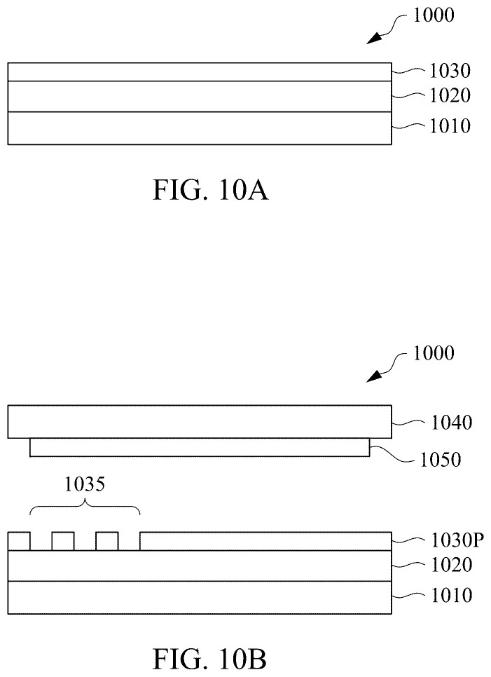

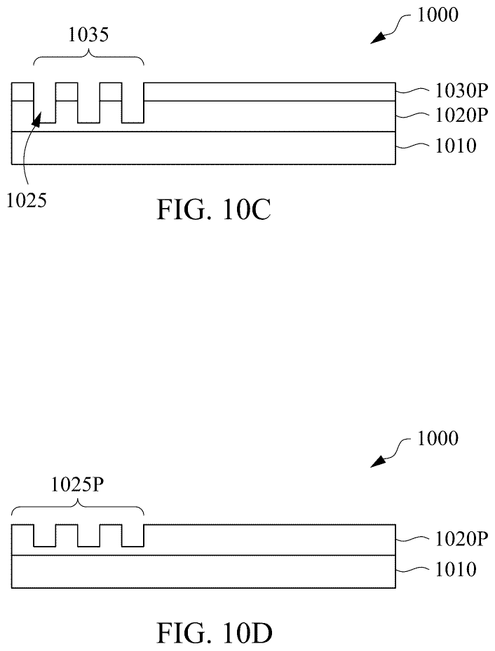

FIG. 9 is a flowchart illustrating a method 900 for fabricating a semiconductor device, in accordance with some embodiments. FIGS. 10A-10D are cross-sectional views of the semiconductor device 1000 at various stages of the method 900, in accordance with some embodiments. The method 900 is discussed in detail below, with reference to the semiconductor devices of FIGS. 10A-10D. At least some steps of the method 900 may be performed via control of an EUV lithography system, such as the lithography system of FIG. 1.

A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material.

In step 902 of FIG. 9, a target layer 1020 to be patterned is formed over a semiconductor substrate 1010, as shown in FIG. 10A. In certain embodiments, the target layer 1020 is the semiconductor substrate 1010. In some embodiments, the target layer 1020 includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer 1020 is formed over an underlying structure, such as isolation structures, transistors or wirings.

In step 904 of FIG. 9, a photoresist layer 1030 is formed over the target layer 1020, as shown in FIG. 10A. The photoresist layer 1030 is sensitive to the radiation from the exposing source during a subsequent photolithography exposing process. In some embodiments, the photoresist layer 1030 is sensitive to EUV light used in the photolithography exposing process. The photoresist layer 1030 may be formed over the target layer by spin-on coating or other suitable technique. The coated photoresist layer 1030 may be further baked to drive out solvent in the photoresist layer 1030.

In step 906 of FIG. 9, the photoresist layer 1030 is patterned using an EUV mask 1040 with a pellicle 1050 as set forth above, as shown in FIG. 10B. The pellicle 1050 includes a pellicle membrane as described herein. The pellicle membrane comprises at least one CNT membrane layer that contains a network of a plurality of CNTs with a least one CNT in the plurality of CNTs coated with a multilayer protective coating of the present disclosure. The patterning of the photoresist layer 1030 includes performing a photolithography exposing process by an EUV exposing system using the EUV mask 1040. During the exposing process, light emitted by a EUV light source is directed onto the EUV mask 1040. The light that passes through the pellicle 1050 and is reflected by the EUV mask 1040 is then collected and directed to the photoresist layer 1030 by a projection optics module. The integrated circuit (IC) design pattern defined on the EUV mask 1040 is imaged to the photoresist layer 1030 to form a latent pattern thereon. Falling particles during the exposing process may be caught by the pellicle membrane so as to keep the EUV mask 1040 clear of the falling particles while the light is being directed onto the EUV mask 1040.

The patterning of the photoresist layer 1030 further includes developing the exposed photoresist layer to form a patterned photoresist layer 1030P having a plurality of openings 1035. In one embodiment where the photoresist layer 1030 is a positive tone photoresist layer, the exposed portions of the photoresist layer 1030 are removed during the developing process. The patterning of the photoresist layer 1030 may further include other process steps, such as various baking steps at different stages. For example, a post-exposure-baking (PEB) process may be implemented after the photolithography exposing process and before the developing process.

In step 908 of FIG. 9, the target layer 1020 is patterned utilizing the patterned photoresist layer 1030P as an etching mask, as shown in FIG. 10C. In some embodiments, the patterning the target layer 1020 includes applying an etching process to the target layer 1020 using the patterned photoresist layer 1030P as an etch mask. The portions of the target layer 1020 exposed within the openings 1035 of the patterned photoresist layer 1030P are etched while the remaining portions are protected from etching. Trenches 1025 are now present in the patterned target layer 1020P.

In step 910 of FIG. 9, the patterned photoresist layer 1030P may be removed by wet stripping or plasma ashing, as shown in FIG. 10D. Further processing steps can then be performed.

One aspect of this description relates to a pellicle. The pellicle includes a pellicle membrane comprising a network of a plurality of carbon nanotubes. At least one carbon nanotube of the plurality of carbon nanotubes is surrounded by a multilayer protective coating including a stress control layer, and a hydrogen permeation barrier layer over the stress control layer. The stress control layer and the hydrogen permeation barrier layer independently include an Me-containing nitride or an Me-containing oxynitride with Me selected from the group consisting of Si, Ti, Y, Hf, Zr, Zn, Mo, Cr and combinations thereof. The Me-containing nitride or the Me-containing oxynitride in the stress control layer has a first Me concentration, and the Me-containing nitride or the Me-containing oxynitride in the hydrogen permeation barrier layer has a second Me concentration less than the first Me concentration. The pellicle further includes a pellicle border attached to the pellicle membrane along a peripheral region of the pellicle membrane, and a pellicle frame attached to the pellicle border.

Another aspect of this description relates to a pellicle-photomask structure. The pellicle-photomask structure includes a pellicle and a photomask. The pellicle include a pellicle membrane comprising a network of a plurality of carbon nanotubes. At least one carbon nanotube of the plurality of carbon nanotubes is surrounded by a multilayer protective coating. The multilayer protective coating includes a stress control layer, a hydrogen permeation barrier layer over the stress control layer, and an interdiffusion layer between the stress control layer and the hydrogen permeation barrier layer. The stress control layer, the hydrogen permeation barrier layer and the interdiffusion layer independently comprise an Me-containing nitride or an Me-containing oxynitride with Me being Si or a transition metal. The Me-containing nitride or the Me-containing oxynitride in the stress control layer has a first Me concentration, the Me-containing nitride or the Me-containing oxynitride in the hydrogen permeation barrier layer has a second Me concentration less than the first Me concentration, and the Me-containing nitride or the Me-containing oxynitride in the interdiffusion layer has a third Me concentration less than the first Me concentration but greater than the second Me concentration.

Still another aspect of this description relates to a method for forming a semiconductor device. The method includes providing an extreme ultraviolet (EUV) light to a photomask through a pellicle on the photomask. The pellicle includes a pellicle membrane comprising a network of a plurality of carbon nanotubes. At least one carbon nanotube of the plurality of carbon nanotubes is surrounded by a multilayer protective coating that includes a stress control layer, and a hydrogen permeation barrier layer over the stress control layer. The stress control layer and the hydrogen permeation barrier layer independently includes an Me-containing nitride or an Me-containing oxynitride with Me selected from the group consisting of Si, Ti, Y, Hf, Zr, Zn, Mo, Cr and combinations thereof. The Me-containing nitride or the Me-containing oxynitride in the stress control layer has a first Me concentration, and the Me-containing nitride or the Me-containing oxynitride in the hydrogen permeation barrier layer has a second Me concentration less than the first Me concentration. The method further includes directing a portion of the EUV light reflected from the photomask onto a photoresist layer on a substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a pellicle, comprising:
forming a protective coating over a core layer comprising a plurality of carbon nanotubes that is disposed on a template substrate, wherein forming the protective coating comprises:
conformally depositing a first coating layer around one or more carbon nanotubes of the plurality of carbon nanotubes; and
conformally depositing a second coating layer over the first coating layer;
attaching a pellicle border to the coating core layer along a peripheral region of the coated core layer;
removing the template substrate; and
attaching the pellicle border to a pellicle frame,
wherein the first coating layer and the second coating layer independently comprise an Me-containing nitride or an Me-containing oxynitride with Me selected from the group consisting of Si, Ti, Y, Hf, Zr, Zn, Mo, Cr and combinations thereof, wherein the Me-containing nitride or the Me-containing oxynitride in the first coating layer has a first Me concentration, and the Me-containing nitride or the Me-containing oxynitride in the second coating layer has a second Me concentration different from the first Me concentration.

2. The method of claim 1, wherein the second Me concentration is less than the first Me concentration.

3. The method of claim 2, wherein the first Me concentration ranges from about 80 atomic % to about 98 atomic %.

4. The method of claim 1, wherein the second Me concentration is greater than the first Me concentration.

5. The method of claim 2, wherein the second Me concentration ranges from about 80 atomic % to about 98 atomic %.

6. The method of claim 1, wherein forming the protective coating further comprises densifying the protective coating using Ar, N₂ or NH₃ plasma.

7. The method of claim 1, wherein forming the protective coating further comprises annealing the protective coating to diffuse the Me element from the first coating layer to the second coating layer, thereby forming an interdiffusion layer having a gradient of the Me element.

8. The method of claim 7, wherein the protective coating is annealed at a temperature ranging from 200° C. to 1000° C.

9. The method of claim 1, further comprising forming a plurality of nanostructures on a surface of each of the one or more carbon nanotubes of the plurality of carbon nanotubes prior to depositing the first coating layer, wherein the plurality of carbon nanostructures comprises Ru, Mo, Zr, Ir, Pt, Rh, Nb, Ti, Cr, W, Co, Fe, Al or Ga.

10. The method of claim 9, wherein the plurality of nanostructures comprises a plurality of nanograins, nanoislands, nanocubes or nanosheets.

11. The method of claim 9, further comprising performing a surface treatment to form hydroxy groups on the surface of each of the one or more carbon nanotubes of the plurality of carbon nanotubes prior to forming the plurality of nanostructures.

12. The method of claim 9, further comprising forming a diffusion inhibition layer to cover the plurality of the nanostructures, wherein the diffusion inhibition layer comprises Y₂O₃, Al₂O₃, TiO₂, HfO₂ or combinations thereof.

13. A method for forming a pellicle, comprising:
forming a protective coating over a core layer comprising a plurality of carbon nanotubes that is disposed on a template substrate, wherein forming the protective coating comprises:
forming a plurality of nanostructures over a surface of at least one carbon nanotube of the plurality of carbon nanotubes, wherein the plurality of nanostructures comprises a metal capable of reacting with hydrogen radicals to form a hydrogen molecule;
depositing a first coating layer over the plurality of nanostructures and the surface of the at least one carbon nanotube of the plurality of carbon nanotubes; and
depositing a second coating layer over the first coating layer;
transfer the core layer from the template substrate to a pellicle border; and
attaching the pellicle bonder to a pellicle frame,
wherein the first coating layer and the second coating layer independently comprise an Me-containing nitride or an Me-containing oxynitride with Me selected from the group consisting of Si, Ti, Y, Hf, Zr, Zn, Mo, Cr and combinations thereof, wherein the Me-containing nitride or the Me-containing oxynitride in the first coating layer has a first Me concentration, and the Me-containing nitride or the Me-containing oxynitride in the second coating layer has a second Me concentration less than the first Me concentration.

14. The method of claim 13, wherein the plurality of nanostructures comprises Ru, Mo, Zr, Ir, Pt, Rh, Nb, Ti, Cr, W, Co or Fe.

15. The method of claim 13, wherein the first and second Me concentrations are no less than 50 atomic %.

16. The method of claim 13, further comprising diffusing the Me element in the first coating layer to the second coating layer by thermally annealing the protective coating to form an interdiffusion layer, wherein the interdiffusion layer has a third Me concentration lower than the first Me concentration, but greater than the second Me concentration.

17. The method of claim 13, wherein the first coating layer and the second coating layer independently have a thickness ranging from 0.5 nm to 10 nm.

18. A method for forming a pellicle membrane comprising forming a protective coating over a core layer comprising a plurality of carbon nanotubes, wherein forming the protective coating comprises:
forming a plurality of nanostructures over a surface of at least one carbon nanotube of the plurality of carbon nanotubes, wherein the plurality of nanostructures comprises a metal capable of reacting with hydrogen radicals to form a hydrogen molecule;
depositing a diffusion inhibition layer over the plurality of nanostructures and the surface of the at least one carbon nanotube of the plurality of carbon nanotubes, the diffusion inhibition layer separating the plurality of nanostructures from one another;
depositing a first coating layer over the plurality of nanostructures and the surface of the diffusion inhibition layer; and
depositing a second coating layer over the first coating layer,
wherein the first coating layer and the second coating layer independently comprise an Me-containing nitride or an Me-containing oxynitride with Me selected from the group consisting of Si, Ti, Y, Hf, Zr, Zn, Mo, Cr and combinations thereof, wherein the Me-containing nitride or the Me-containing oxynitride in the first coating layer has a first Me concentration, and the Me-containing nitride or the Me-containing oxynitride in the second coating layer has a second Me concentration less than the first Me concentration.

19. The method of claim 18, wherein the diffusion inhibition layer comprises a metal oxide.

20. The method of claim 19, wherein the diffusion inhibition layer comprises Y₂O₃, Al₂O₃, TiO₂ or HfO₂.
